(19) United States
(12) Patent Application Publication
(10) Pub. No.: US 2025/0248060 A1
(43) Pub. Date: Jul. 31, 2025

(54) SEMICONDUCTOR DEVICE AND SEMICONDUCTOR DEVICE MANUFACTURING METHOD

(71) Applicant: Sharp Display Technology Corporation, Kameyama City, Mie (JP)

(72) Inventors: Yohsuke KANZAKI, Kameyama City, Mie (JP); Takao SAITOH, Kameyama City, Mie (JP); Masaki FUJIWARA, Kameyama City, Mie (JP); Masahiko MIWA, Kameyama City, Mie (JP); Masaki YAMANAKA, Kameyama City, Mie (JP); Yi SUN, Kameyama City, Mie (JP); Kouhei KAMATANI, Kameyama City, Mie (JP)

(21) Appl. No.: 18/856,685

(22) PCT Filed: Jun. 17, 2022
(86) PCT No.: PCT/JP2022/024279

§ 371 Date: Oct. 14, 2024

(51) Int. Cl. H10D 30/01; H10D 30/67; H10K 59/12

(52) U.S. Cl. CPC H10D 30/031; H10D 30/6755; H10K 59/1201

(57) ABSTRACT

A method for manufacturing a semiconductor device including an oxide semiconductor layer, a gate insulating film, and a gate electrode layered in this order on a substrate, includes: forming the oxide semiconductor layer on the substrate; forming the gate insulating film on the oxide semiconductor layer; forming the gate electrode on the gate insulating film; and implanting an impurity corresponding to an oxygen-defect-inducing factor from above the gate insulating film. In the implanting, the impurity is implanted so that a peak of concentration of the impurity is located in the gate insulating film and the impurity corresponding to the oxygen-defect-inducing factor is implanted from above the gate insulating film after the gate electrode is formed on the gate insulating film and a photoresist is formed covering the gate electrode.

### TECHNICAL FIELD

The disclosure relates to a semiconductor device including an oxide semiconductor layer and a method for manufacturing the same.

### BACKGROUND ART

In general, in a semiconductor device including an oxide semiconductor layer, it is necessary to reduce the resistance of regions in the oxide semiconductor layer which are in contact with a source electrode and a drain electrode. For example, PTL 1 and 2 disclose that an oxygen-defect-inducing factor is introduced into an oxide semiconductor layer to reduce the resistance of regions in the oxide semiconductor layer which are in contact with a source electrode and a drain electrode.

### CITATION LIST

### Patent Literature

PTL 1: JP 5702128 B

PTL 2: JP 5781246 B

### SUMMARY

### Technical Problem

However, a stable low-resistance region cannot be formed only by introducing the oxygen-defect-inducing factor into the oxide semiconductor layer. This is because when the semiconductor device is heated to about 300° C. to 350° C. in a heating process performed after a process of introducing the oxygen-defect-inducing factor into the oxide semiconductor layer, oxygen is supplied into the oxide semiconductor layer and the resistance of the low-resistance region is increased.

The disclosure has been made to solve the problem described above, and an object thereof is to provide a semiconductor device including an oxide semiconductor layer formed with a stable resistance region and a method for manufacturing the same.

### Solution to Problem

A semiconductor device according to an aspect of the disclosure includes an oxide semiconductor layer, a gate insulating film, and a gate electrode layered in this order on a substrate, wherein the oxide semiconductor layer includes a channel region overlapping the gate electrode interposed by the gate insulating film, a first region electrically connected to a source electrode, and a second region electrically connected to a drain electrode, an impurity corresponding to an oxygen-defect-inducing factor is implanted in at least the gate insulating film, and the first region and the second region, and an amount of impurity implanted in the gate insulating film is greater than an amount of impurity implanted in the first region and the second region.

A method for manufacturing a semiconductor device according to an aspect of the disclosure, with the semiconductor device including an oxide semiconductor layer, a gate insulating film, and a gate electrode layered in this order on a substrate, includes forming the oxide semiconductor layer on the substrate; forming the gate insulating film on the oxide semiconductor layer; forming the gate electrode on the gate insulating film; and implanting an impurity corresponding to an oxygen-defect-inducing factor from above the gate insulating film, wherein in the implanting, the impurity is implanted so that a peak of concentration of the impurity is located in the gate insulating film.

### Advantageous Effects of Disclosure

According to the disclosure, it is possible to provide a semiconductor device including an oxide semiconductor layer in which a stable low-resistance region is formed.

### BRIEF DESCRIPTION OF DRAWINGS

FIG. 1 is a schematic cross-sectional view schematically illustrating a transistor according to a first embodiment.

FIG. 2 is a schematic view for explaining an impurity implantation process included in a manufacturing process of the transistor illustrated in FIG. 1.

FIG. 3 is a graph showing SIMS depth direction analysis results of each atom in the transistor illustrated in FIG. 1.

FIG. 4 is a graph showing SIMS depth direction analysis results of each atom in the transistor illustrated in FIG. 1.

FIG. 5 is a graph showing SIMS depth direction analysis results of each atom in the transistor illustrated in FIG. 1.

FIG. 6 is a graph showing TFT characteristics according to the differences in sheet resistance value of an oxide semiconductor layer.

FIG. 7 is a graph showing TFT characteristics according to the differences in sheet resistance value of an oxide semiconductor layer.

FIG. 8 is a graph showing TFT characteristics according to the differences in sheet resistance value of an oxide semiconductor layer.

FIG. 9 is a schematic cross-sectional view illustrating an impurity implantation process according to a modified example of the first embodiment.

FIG. 10 is a schematic cross-sectional view schematically illustrating a transistor according to a second embodiment.

FIG. 11 is a schematic view for explaining an impurity implantation process included in a manufacturing process of the transistor illustrated in FIG. 10.

FIG. 12 is a schematic cross-sectional view schematically illustrating a transistor according to a third embodiment.

FIG. 13 is a schematic view for explaining a preliminary impurity implantation process included in a manufacturing process of the transistor illustrated in FIG. 12.

FIG. 14 is a schematic view for explaining an impurity implantation process included in a manufacturing process of the transistor illustrated in FIG. 12.

FIG. 15 is a schematic cross-sectional view schematically illustrating a transistor according to a fourth embodiment.

FIG. 16 is a schematic plan view illustrating a configuration of a display device according to an example.

FIG. 17 is a schematic cross-sectional view illustrating a configuration of a display region of the display device illustrated in FIG. 16.

FIG. 18 is a schematic view illustrating an example of a configuration of a light-emitting element according to an example.

### DESCRIPTION OF EMBODIMENTS

### First Embodiment

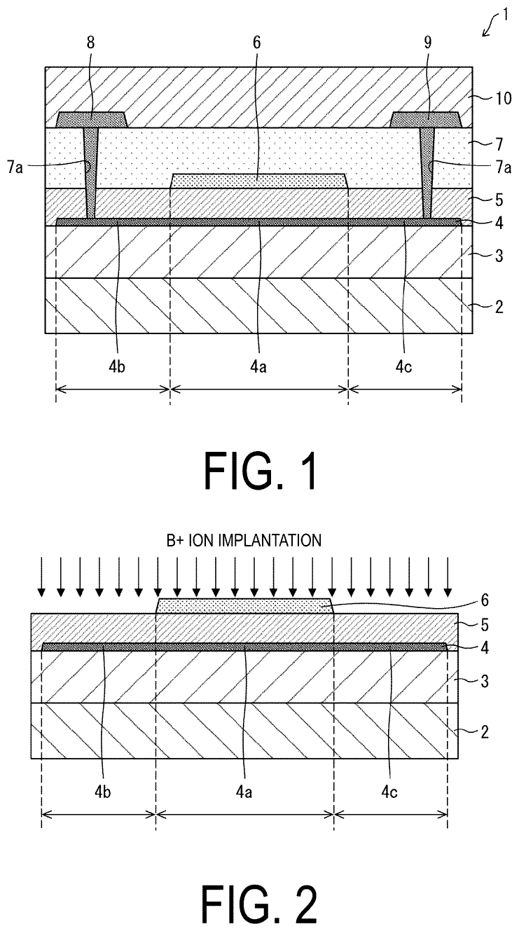

A first embodiment of the disclosure will be described below with reference to FIGS. 1 to 8. Here, the semiconductor device of the disclosure will be described as a transistor used in a display device.

### Overview of Transistor 1

FIG. 1 is a schematic cross-sectional view schematically illustrating a transistor 1 according to the present embodiment. The transistor 1 is, for example, a thin film transistor (TFT) and is formed by layering an inorganic insulating film 3, an oxide semiconductor layer 4, a gate insulating film 5, a gate electrode 6, a passivation film 7, terminal electrodes (a source electrode 8 and a drain electrode 9), and a flattening film 10 on a substrate 2 in this order.

The inorganic insulating film 3 is made of SiO₂ or the like. The oxide semiconductor layer 4 is provided on the inorganic insulating film 3 for each transistor 1. That is, the oxide semiconductor layer 4 is separated from the oxide semiconductor layers 4 of other transistors 1.

The oxide semiconductor layer 4 includes a channel region 4a overlapping the gate electrode on the other side of the gate insulating film, a first region 4b electrically connected to the source electrode 8, and a second region 4c electrically connected to the drain electrode 9. The first region 4b and the second region 4c are regions (low-resistance regions) with a resistance lower than the channel region 4a. Forming the low-resistance regions will be described in detail later.

The gate insulating film 5 covers the oxide semiconductor layer 4 above the inorganic insulating film 3. The gate electrode 6 overlaps the channel region 4a of the oxide semiconductor layer 4 above the gate insulating film 5.

The passivation film 7 is made of SiO₂ or the like and covers the gate electrode 6 above the gate insulating film 5. In the transistor 1, the source electrode 8 and the drain electrode 9 are provided above the passivation film 7.

The source electrode 8 is electrically connected to the first region 4b via a contact hole 7a provided in the gate insulating film 5 and the passivation film 7. The drain electrode 9 is electrically connected to the second region 4c via a contact hole 7a provided in the gate insulating film 5 and the passivation film 7.

The flattening film 10 is made of polyimide or acrylic resin and covers the source electrode 8 and the drain electrode 9 above the passivation film 7. The film covering the source electrode 8 and the drain electrode 9 above the passivation film 7 may be a passivation film other than the flattening film 10.

### Method for Manufacturing Transistor 1

A method for manufacturing the transistor 1 will be described with reference to FIGS. 1 and 2. FIG. 2 is a schematic view for explaining an impurity implantation process included in the manufacturing process of the transistor 1.

First, the inorganic insulating film 3 is formed on the substrate 2. For example, a glass substrate, a silicon substrate, a plastic substrate having heat resistance, or the like can be used as the substrate 2. As a material of the plastic substrate, polyethylene terephthalate (PET), polyethylene naphthalate (PEN), polyethersulfone (PES), acrylic resin, polyimide, or the like can be used.

As the inorganic insulating film 3, an SiO₂ film is formed by a CVD method. The inorganic insulating film 3 is not limited to an SiO₂ film, and may be formed of, for example, silicon oxide (SiOₓ), silicon nitride (SiNₓ), silicon oxynitride (SiOₓN_{y}; x>y), silicon nitride oxide (SiNₓO_{y}; x>y), aluminum oxide, tantalum oxide, and the like. In addition, the inorganic insulating film 3 may be a plurality of layers instead of a single layer.

Next, the oxide semiconductor layer 4 is formed on the inorganic insulating film 3 (oxide semiconductor layer forming process). The oxide semiconductor layer 4 is, for example, an In—Ga—Zn—O based semiconductor film having a thickness ranging from 30 nm to 100 nm and is formed by a sputtering method. The oxide semiconductor layer 4 is formed in an island shape corresponding to one transistor 1 by patterning by a photolithography process and etching.

Further, the gate insulating film 5 covers the oxide semiconductor layer 4 above the inorganic insulating film 3 (gate insulating film forming process). The gate insulating film 5 is formed by depositing silicon oxide (SiOₓ) on the inorganic insulating film 3 by a CVD method. The gate insulating film 5 may be formed of the same material as the inorganic insulating film 3 or may be formed of a different material. The gate insulating film 5 may be formed as one layer or may have a layered structure including a plurality of layers.

The gate electrode 6 is formed on the gate insulating film 5 (gate electrode forming process). The gate electrode 6 is a metal film and is formed by sputtering. The gate electrode 6 may be, for example, a metal film including an element selected from aluminum (Al), tungsten (W), molybdenum (Mo), tantalum (Ta), chromium (Cr), titanium (Ti), and copper (Cu), may be an alloy film or the like including these elements as components thereof, or may be a layered film including a plurality of these films. The gate electrode 6 is formed at a desired position and in a desired shape by a photolithography process and etching.

Next, as illustrated in FIG. 2, in a state where the gate electrode 6 is formed, an impurity serving as an oxygen-defect-inducing factor is implanted from above the gate insulating film 5 (impurity implantation process). Boron ions (B+) are used as impurity. By this impurity implantation process, boron ions (B+), which are an impurity serving as an oxygen-defect-inducing factor, are implanted into the gate insulating film 5 and the first region 4b and the second region 4c of the oxide semiconductor layer 4. The resistance of the first region 4b and the second region 4c into which the boron ions (B+) are implanted is reduced. This is because the implantation of boron ions (B+) increases the oxygen defect level of the oxide semiconductor layer 4, thus increasing the carrier density in the oxide semiconductor layer 4 and decreasing the resistance. On the other hand, since the channel region 4a of the oxide semiconductor layer 4 is covered with the gate electrode 6, when boron ions (B+) are implanted, the gate electrode 6 function as a mask, and boron ions (B+) are hardly implanted.

In the impurity implantation process, boron ions (B+) are implanted into the gate insulating film 5 covering the oxide semiconductor layer 4 so that the peak of the concentration of the boron ions (B+) is reached. Specifically, boron ions (B+) are implanted at the interface between the gate insulating film 5 and the oxide semiconductor layer 4 so that the peak of the concentration of boron ions (B+) is reached. Thus, oxygen defects are efficiently formed at the interface between the gate insulating film 5 and the oxide semiconductor layer 4, and the resistance of the oxide semiconductor layer 4 is reduced.

As described above, when the amount of boron ions (B+) implanted into the gate insulating film 5 is greater than the amount of boron ions (B+) implanted into the first region 4b and the second region 4c of the oxide semiconductor layer 4, the first region 4b and the second region 4c of the oxide semiconductor layer 4 are less likely to be increased in resistance by the supply of oxygen even if oxygen is supplied to the oxide semiconductor layer 4 by heating in a subsequent process and are kept in a low-resistance state. As a result, the transistor 1 including the oxide semiconductor layer 4 in which the low-resistance regions (the first region 4b and the second region 4c) are stably formed can be realized. The relationship between the implantation of the boron ions (B+) and the maintaining of the low resistance of the first region 4b and the second region 4c in the oxide semiconductor layer 4 will be described in detail later.

Next, the passivation film 7 is formed on the gate insulating film 5 covering the gate electrode 6. The passivation film 7 is formed by depositing SiO₂ or the like on the gate insulating film 5 by a CVD method. The passivation film 7 may be formed as one layer or may have a layered structure including a plurality of layers.

The contact hole 7a exposing a portion of the oxide semiconductor layer 4 is formed in the gate insulating film 5 and the passivation film 7 by a known photolithography process. Here, the two contact holes 7a are formed exposing the first region 4b and the second region 4c of the oxide semiconductor layer 4, respectively.

Thereafter, a conductive film for electrodes for forming the source electrode 8 and the drain electrode 9 is formed on the passivation film 7 and in the contact holes 7a. The material exemplified by the gate electrode 6 (aluminum (Al) or the like) is used for the conductive film for electrodes. The source electrode 8 and the drain electrode 9 separated from each other are formed by patterning the formed conductive film for electrodes by a photolithography process and etching.

Finally, the flattening film 10 is formed on the passivation film 7 covering the source electrode 8 and the drain electrode 9. The flattening film 10 is formed by depositing SiO₂ or the like on the passivation film 7 by a CVD method.

Through the above process, the transistor 1 illustrated in FIG. 1 is manufactured. In the manufacture of the transistor 1, after the oxide semiconductor layer 4 and the gate insulating film 5 are formed on the inorganic insulating film 3, an additional heating process is performed at the stage of forming the organic/inorganic insulating films as the flattening film 10 and the passivation film 7. Thus, there is a possibility that the first region 4b and the second region 4c of the oxide semiconductor layer 4 are supplied with oxygen and cannot maintain a low resistance state. However, as a result of intensive studies by the inventors of the present application, as described above, by implanting boron ions (B+) so that the peak of the concentration of boron ions (B+) is located in the gate insulating film 5 covering the oxide semiconductor layer 4, oxygen deficiency is efficiently formed at the interface between the gate insulating film 5 and the oxide semiconductor layer 4, and the low resistance of the first region 4b and the second region 4c of the oxide semiconductor layer 4 can be maintained.

Hereinafter, maintaining low resistance in the first region 4b and the second region 4c of the oxide semiconductor layer 4 will be described.

### Maintaining Low Resistance

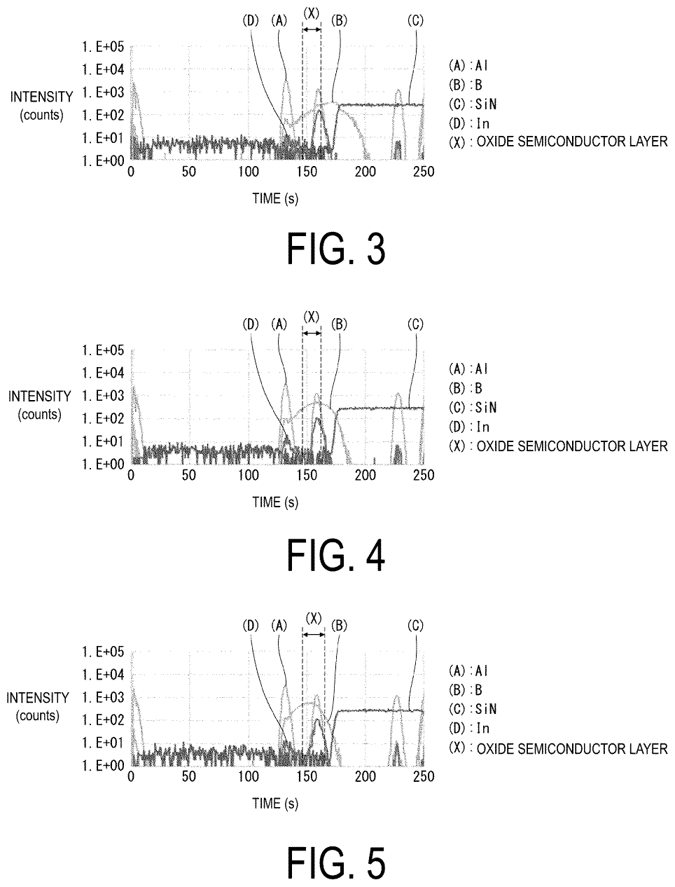

FIGS. 3 to 5 are graphs showing analysis results from analysis (SIMS) in the depth direction using sputtering. In the graphs of FIGS. 3 to 5, the horizontal axis represents the sputtering time, and the vertical axis represents the concentration of atoms. FIGS. 3 to 5 are graphs in which the concentrations and concentration peak positions of (A) aluminum (Al), (C) silicon nitride (SiN), and (D) indium (In) are the same, and only the concentration peak position of (B) boron ions (B+) is different.

In the graph of FIG. 3, the concentration peak of boron ions (B+) is set at the interface between the oxide semiconductor layer 4 and the lower insulating film (at or near the boundary between the oxide semiconductor layer 4 and the inorganic insulating film 3) indicated by (X). Here, the acceleration voltage at the time of implantation of boron ions (B+) is set to 30 kV. In this case, the sheet resistance value of the oxide semiconductor layer 4 was changed from 1 kΩ/□ immediately after the implantation of the boron ions (B+) to 15 kΩ/□ after the additional heating process.

In the graph of FIG. 4, the concentration peak of boron ions (B+) is set inside the oxide semiconductor layer 4 indicated by (X). Here, the acceleration voltage at the time of implantation of boron ions (B+) is set to 20 kV. In this case, the sheet resistance value of the oxide semiconductor layer 4 was changed from 1 kΩ/□ immediately after the implantation of the boron ions (B+) to 20 kΩ/□ after the additional heating process.

In the graph of FIG. 5, the concentration peak of boron ions (B+) is set at the interface between the oxide semiconductor layer 4 and the upper insulating film (at or near the boundary between the oxide semiconductor layer 4 and the gate insulating film 5) indicated by (X). Here, the acceleration voltage at the time of implantation of boron ions (B+) is set to 15 kV. In this case, the sheet resistance value of the oxide semiconductor layer 4 was changed from 1 kΩ/□ immediately after the implantation of the boron ions (B+) to 2 kΩ/□ after the additional heating process.

From the above, it can be confirmed that the concentration peak position of the boron ions (B+) with respect to the oxide semiconductor layer 4 changes in the analysis result in the SIMS depth direction in the case where the acceleration voltage at the time of implantation of the boron ions (B+) is changed to 30 kV, 20 kV, and 15 kV. Here, in any case where the acceleration voltage at the time of implantation of boron ions (B+) is 30 kV, 20 kV, or 15 kV, the sheet resistance value immediately after implantation of boron ions (B+) is about 1 kΩ, which does not affect the TFT characteristics. However, when a heating process is added after each process, the sheet resistance value does not significantly increase when the acceleration voltage is 15 kV (FIG. 5) and hardly affects the TFT characteristics, but when the acceleration voltage is 30 kV or 20 kV (FIGS. 3 and 4), the sheet resistance value increases and affects the TFT characteristics.

That is, as shown in FIG. 5, when the concentration peak of boron ions (B+) is set at the interface between the oxide semiconductor layer 4 and the upper insulating film (at or near the boundary between the oxide semiconductor layer 4 and the gate insulating film 5) indicated by (X), the sheet resistance value after the additional heating process increases the minimum amount, which does not significantly affect the TFT characteristics. On the other hand, as shown in FIG. 3, when the concentration peak of boron ions (B+) is set at the interface between the oxide semiconductor layer 4 and the lower insulating film (at or near the boundary between the oxide semiconductor layer 4 and the inorganic insulating film 3) indicated by (X), and as shown in FIG. 4, when the concentration peak of boron ions (B+) is set within the oxide semiconductor layer 4 indicated by (X), the sheet resistance value after the additional heating process greatly increases, which affects the TFT characteristics.

From the above, to maintain the low resistance of the oxide semiconductor layer 4, the concentration peak of boron ions (B+) is preferably set at the interface between the oxide semiconductor layer 4 and the upper insulating film (at or near the boundary between the oxide semiconductor layer 4 and the gate insulating film 5) indicated by (X).

### TFT Characteristics

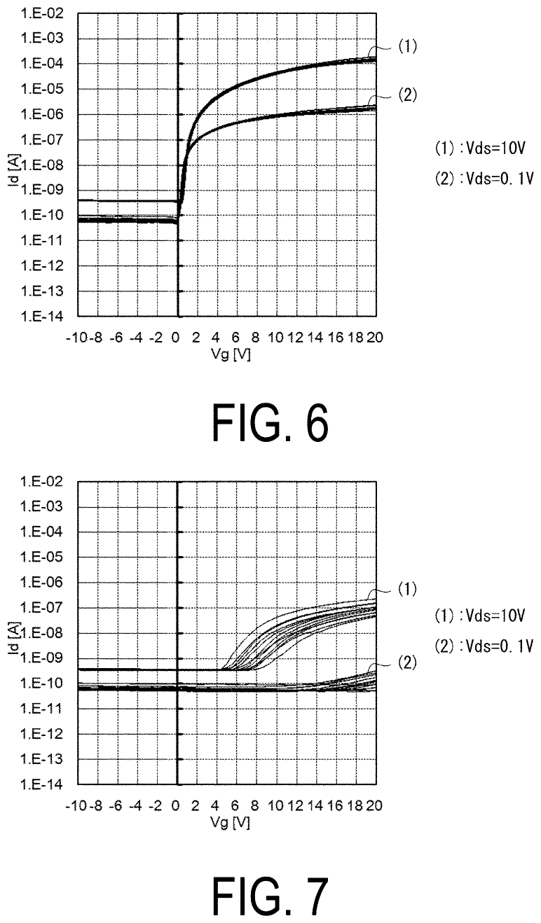

FIGS. 6 to 8 are graphs showing TFT characteristics according to the differences in sheet resistance value of the oxide semiconductor layer 4. These graphs show the relationship between a voltage (inter-electrode voltage) Vds between the drain electrode 9 and the source electrode 8 and the on-current indicating the characteristics of the respective TFTs when the voltage Vds is set to 10 V and 0.1 V.

FIG. 6 is a graph showing the on-characteristics of the TFT when the sheet resistance value of the oxide semiconductor layer 4 immediately after implantation of boron ions (B+) (initial state) is about 1 kΩ/□. Here, the initial state indicates a state before the additional heating process.

FIG. 7 is a graph showing the on-characteristics of the TFT after the concentration peak of the boron ions (B+) is set in the oxide semiconductor layer 4 indicated by (X) as shown in FIG. 4, the boron ions (B+) are implanted, and the additional heating process is performed.

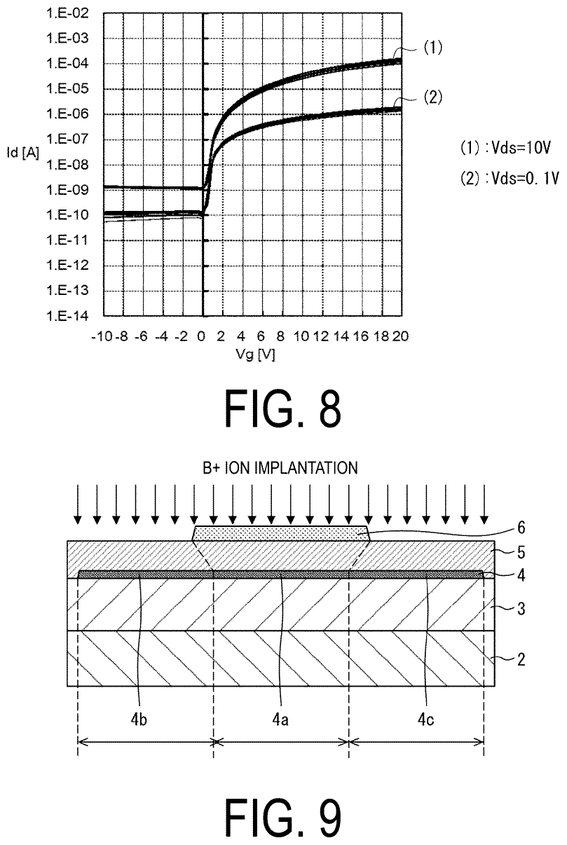

FIG. 8 is a graph showing the on-characteristics of the TFT after the concentration peak of the boron ions (B+) is set at the interface between the oxide semiconductor layer 4 and the upper insulating film (at or near the boundary between the oxide semiconductor layer 4 and the gate insulating film 5) indicated by (X) as shown in FIG. 5, the boron ions (B+) are implanted, and the additional heating process is performed.

As described above, when the source electrode 8 and the drain electrode 9 are formed after the impurity implantation process and the TFT having good characteristics is in the initial state (graph of FIG. 6), an additional heating process treatment (additional heating process) is performed at the stage of forming the organic/inorganic insulating film as the passivation film 7 and the flattening film 10 above the source electrode 8 and the drain electrode 9. In this case, the low-resistance state of the oxide semiconductor layer 4 cannot be maintained by the additional heating process, and the oxide semiconductor layer 4 enters a high-resistance state in which the sheet resistance value is 20 kΩ/□ or greater. As shown in FIG. 7, when the oxide semiconductor layer 4 is in the high resistance state, the on-characteristics of the TFT are lowered and the on-current is significantly lowered. However, if the concentration peak of the boron ions (B+) is set to the optimal conditions described above, that is, at the interface between the oxide semiconductor layer 4 and the upper insulating film (at or near the boundary between the oxide semiconductor layer 4 and the gate insulating film 5) indicated by (X) as shown in FIG. 5, the increase in the sheet resistance value can be kept to a minimum even after the additional heating process, and on-characteristics of the TFT comparable to that of the initial state can be obtained as shown in FIG. 8. Thus, it is possible to suppress a significant decrease in the on-current.

### Advantageous Effects

In the transistor 1, boron ions (B+) are implanted at the interface between the gate insulating film 5 and the oxide semiconductor layer 4 so that the peak of the concentration of boron ions (B+) is reached. Thus, oxygen defects are efficiently formed at the interface between the gate insulating film 5 and the oxide semiconductor layer 4, and the resistance of the oxide semiconductor layer 4 is reduced. Thus, the first region 4b and the second region 4c of the oxide semiconductor layer 4 are less likely to be increased in resistance by the supply of oxygen even if oxygen is supplied to the oxide semiconductor layer 4 in the case of a heating process being performed after the implantation of the boron ions (B+) and are kept in a low-resistance state. Thus, even in a case where the heating process is performed after the boron ions (B+) are implanted into the oxide semiconductor layer 4, the low-resistance regions (the first region 4b and the second region 4c) of the oxide semiconductor layer 4 are kept in the low-resistance state. Thus, the transistor 1 in which the low-resistance regions (the first region 4b and the second region 4c) of the oxide semiconductor layer 4 are stably formed is obtained.

In the first embodiment, as illustrated in FIG. 2, boron ions (B+) are not implanted into the regions (channel region 4a) where the gate electrode 6 projects over the oxide semiconductor layer 4. In the modified example described below, boron ions (B+) travel around the gate electrode 6 and are implanted into the oxide semiconductor layer 4.

### Modified Example

FIG. 9 is a schematic cross-sectional view for explaining an example in which boron ions (B+) travel around the gate electrode 6 and are implanted into the oxide semiconductor layer 4.

As illustrated in FIG. 9, the boron ions (B+) travel around the gate electrode 6 and are implanted into the oxide semiconductor layer 4. In this case, as illustrated in FIG. 2, the channel region 4a, which is a region where the boron ions (B+) are not implanted, is smaller than the region where the gate electrode 6 projects over the oxide semiconductor layer 4. There is an advantage that the channel length can be made shorter than the channel length formed by photolithography, that is, the length in the width direction of the region where the gate electrode 6 projects over the oxide semiconductor layer 4. In addition, since the first region 4b and the second region 4c are increased in size, the on-current of the TFT can be increased. This improves the TFT characteristics.

As described above, since the resistance value of the oxide semiconductor layer 4 can be reduced by implanting boron ions (B+), a plurality of regions having different resistance values can be formed in the oxide semiconductor layer 4 by adjusting the amount of boron ions (B+) implanted into the oxide semiconductor layer 4. In the following second and third embodiments, examples in which a plurality of regions having different resistance values are formed in the oxide semiconductor layer 4 will be described.

### Second Embodiment

Another embodiment of the disclosure will be described below. Further, members having the same functions as those of the members described in the above-described embodiments will be denoted by the same reference numerals and signs, and the description thereof will not be repeated for the sake of convenience of description.

### Overview of Transistor 21

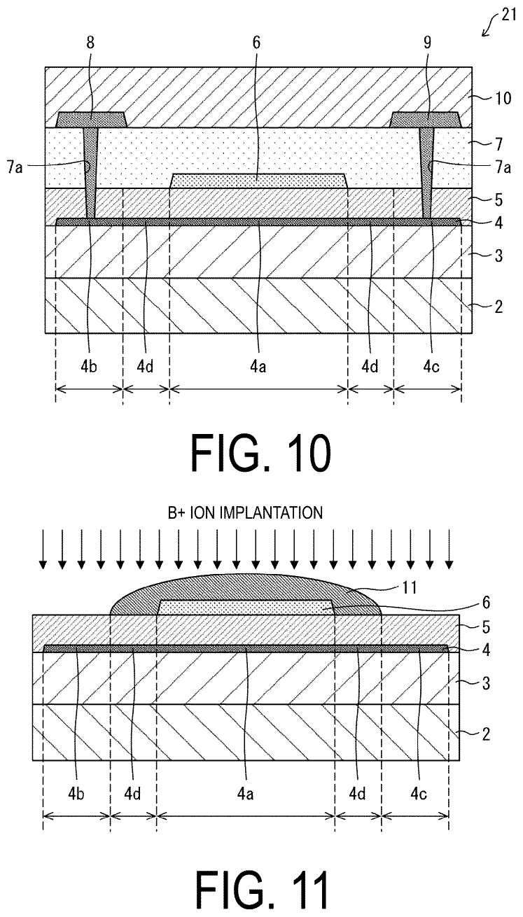

FIG. 10 is a schematic cross-sectional view schematically illustrating a transistor 21 according to the present embodiment. The transistor 21 has substantially the same configuration as the transistor 1 according to the first embodiment except that the oxide semiconductor layer 4 further includes a third region 4d formed between the channel region 4a and the first region 4b and between the channel region 4a and the second region 4c. The third region 4d is implanted with boron ions (B+), and the amount of boron ions (B+) implanted into the third region 4d is less than the amount of boron ions (B+) implanted into the first region 4b and the second region 4c. That is, a high-resistance region (third region 4d) having a higher resistance value than the first region 4b and the second region 4c is formed on either side of the channel region 4a of the oxide semiconductor layer 4.

### Method for Manufacturing Transistor 21

A method for manufacturing the transistor 21 will be described with reference to FIG. 11. FIG. 11 is a schematic view for explaining an impurity implantation process included in the manufacturing process of the transistor 21. The method for manufacturing the transistor 21 is substantially the same as the method for manufacturing the transistor 1 according to the first embodiment except that a process for forming the third region 4d in the oxide semiconductor layer 4 is added. Specifically, in the impurity implantation process, after the gate electrode 6 is formed on the gate insulating film 5 and a photoresist 11 is formed covering the gate electrode 6, boron ions (B+) are implanted from above the gate insulating film 5.

That is, boron ions (B+) are not implanted immediately after the gate electrode 6 is formed on the gate insulating film 5, but as illustrated in FIG. 11, the photoresist 11 is patterned in a predetermined pattern on the gate insulating film 5 covering the gate electrode 6, and then boron ions (B+) are implanted.

The photoresist 11 functions as a mask when boron ions (B+) are implanted into the oxide semiconductor layer 4. Thus, although almost no boron ions (B+) are implanted into the region (third region 4d) of the oxide semiconductor layer 4 where the photoresist 11 projects over, there is a possibility of boron ions (B+) travelling around from both side ends of the photoresist 11 and being implanted. As described above, since boron ions (B+) are hardly implanted into the third region 4d, the carrier density due to boron ions (B+) hardly increases and the resistance does not decrease.

By appropriately changing the size of the photoresist 11, it is possible to adjust the size of the third region 4d, that is, the size of the region in which the resistance is not reduced in the oxide semiconductor layer 4.

### Advantageous Effects

As described above, by using the photoresist 11, it is possible to protect a region of the oxide semiconductor layer 4 where boron ions (B+) are not desired to be implanted. Thus, it is possible to form the high-resistance third region 4d where boron ions (B+) are hardly implanted on both sides of the channel region 4a in the oxide semiconductor layer 4. Since the third region 4d has a function equivalent to that of a LDD (Lightly Doped Drain) generally known in low-temperature polysilicon TFT techniques, a TFT including the oxide semiconductor layer 4 in which the LDD is formed can be realized.

As described above, since the high-resistance third regions 4d are formed on both sides of the channel region 4a of the oxide semiconductor layer 4, in the TET in which a high electric field is applied to the source and drain electrodes, the breakdown voltage between the source and drain electrodes is improved, and a high-breakdown voltage device can be realized.

### Third Embodiment

Another embodiment of the disclosure will be described below. Further, members having the same functions as those of the members described in the above-described embodiments will be denoted by the same reference numerals and signs, and the description thereof will not be repeated for the sake of convenience of description.

### Overview of Transistor 31

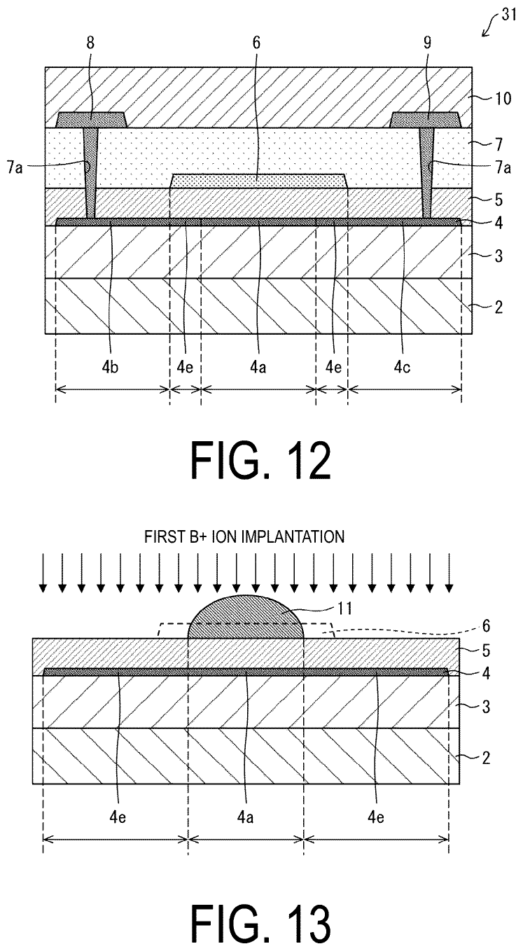

FIG. 12 is a schematic cross-sectional view schematically illustrating a transistor 31 according to the present embodiment. The transistor 31 has substantially the same configuration as that of the transistor 1 according to the first embodiment, but is different in that the region of the oxide semiconductor layer 4 that the gate electrode 6 projects over includes the channel region 4a and a fourth region 4e formed on both sides of the channel region 4a, and the resistance value of the fourth region 4e is higher than the resistance value of the first region 4b and the second region 4c but lower than the resistance value of the channel region 4a. That is, a medium-resistance region (fourth region 4e) having a higher resistance value than the first region 4b and the second region 4c and a lower resistance value than the channel region 4a is formed on either side of the channel region 4a of the oxide semiconductor layer 4.

### Method for Manufacturing Transistor 31

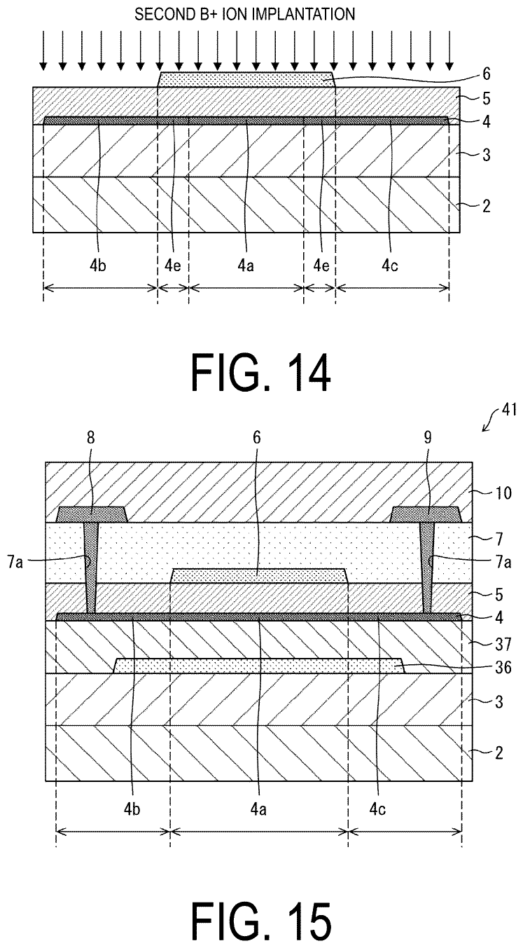

A method for manufacturing the transistor 31 will be described with reference to FIGS. 13 and 14. FIG. 13 is a schematic view for explaining a preliminary impurity implantation process included in the manufacturing process of the transistor 31. FIG. 14 is a schematic view for explaining an impurity implantation process included in the manufacturing process of the transistor 31. The method for manufacturing the transistor 31 is substantially the same as the method for manufacturing the transistor 1 according to the first embodiment except that a process for forming the fourth region 4e in the oxide semiconductor layer 4 is added.

First, before the gate electrode 6 is formed on the gate insulating film 5, the photoresist 11 is formed at a predetermined position on the gate insulating film 5 (photoresist forming process). As illustrated in FIG. 13, the photoresist 11 is formed in a region on the gate insulating film 5 which includes a region (indicated by a dotted line in FIG. 13) where the gate electrode 6 is to be formed and is wider than this region.

Next, after a photoresist 11 is formed on the gate insulating film 5, boron ions (B+) are preliminarily implanted from above the gate insulating film 5 (preliminary impurity implantation process). In the preliminary impurity implantation process, boron ions (B+) are implanted beyond the interface between the gate insulating film 5 and the oxide semiconductor layer 4 and on the oxide semiconductor layer 4 side so that the peak of the concentration of boron ions (B+) is reached.

In the preliminary impurity implantation process, the photoresist 11 functions as a mask when boron ions (B+) are implanted into the oxide semiconductor layer 4. Thus, almost no boron ions (B+) are implanted into the region (channel region 4a) of the oxide semiconductor layer 4 the photoresist 11 projects over, and boron ions (B+) are implanted into the fourth region 4e outside the channel region 4a which is not masked by the photoresist 11, so that the resistance is reduced.

Subsequently, after boron ions (B+) are implanted in the preliminary impurity implantation process, the photoresist 11 is removed (photoresist removal process).

Next, the gate electrode 6 is formed on the gate insulating film 5 from which the photoresist 11 has been removed in the photoresist removal process, and boron ions (B+) are implanted from above the gate insulating film 5 (impurity implantation process). In this impurity implantation process, boron ions (B+) are implanted in the same manner as in the impurity implantation process of the first embodiment.

In this impurity implantation process, as illustrated in FIG. 14, the gate electrode 6 functions as a mask when boron ions (B+) are implanted into the oxide semiconductor layer 4. Thus, in the preliminary impurity implantation process, boron ions (B+) are implanted again into regions not masked by the gate electrode 6 in the fourth region 4e into which boron ions (B+) have been implanted. Thus, the resistance of the region into which boron ions (B+) are implanted twice is further reduced as compared with the region (fourth region 4e) into which boron ions (B+) are implanted once.

The amount of boron ions (B+) implanted in the preliminary impurity implantation process is preferably less than the amount of boron ions (B+) implanted in the impurity implantation process.

### Advantageous Effects

As described above, by selectively implanting boron ions (B+) using the photoresist 11 before forming the gate electrodes 6, it is possible to form a region (fourth region 4e) in the oxide semiconductor layer 4 having a slightly low resistance at or near the channel region 4a where the gate electrode 6 projects over. Thus, a TFT having a channel length (width of the channel region 4a) shorter than the width of the gate electrode 6 can be formed.

As with the third region 4d of the second embodiment, since the fourth region 4e has a function equivalent to that of a LDD (Lightly Doped Drain) generally known in low-temperature polysilicon TFT techniques, a TFT including the oxide semiconductor layer 4 in which the LDD is formed can be realized. In addition, since the fourth region 4e is a part of the region where the gate electrode 6 projects over, the fourth region 4e can be made shorter in width than the third region 4d of the second embodiment formed outside the region where the gate electrode 6 projects over.

The transistors 1, 21, and 31 according to the first to third embodiments described above each include one gate electrode 6. However, the disclosure is not limited to this, and two gate electrodes may be formed. In the fourth embodiment described below, two gate electrodes are formed.

### Fourth Embodiment

Another embodiment of the disclosure will be described below. Further, members having the same functions as those of the members described in the above-described embodiments will be denoted by the same reference numerals and signs, and the description thereof will not be repeated for the sake of convenience of description.

### Overview of Transistor 41

FIG. 15 is a schematic cross-sectional view schematically illustrating a transistor 41 according to the present embodiment. The transistor 41 has substantially the same configuration as that of the transistor 1 of the first embodiment, but is different in that a gate electrode 36 is provided in the lower portion in addition to the gate electrode 6 in the upper portion.

That is, in the transistor 41, as illustrated in FIG. 15, the gate electrode 36 is formed on the inorganic insulating film 3, and the gate insulating film 37 is formed on the inorganic insulating film 3 covering the gate electrode 36. The gate electrode 36 has a width greater than the width of the region where the gate electrode 6 projects over.

The oxide semiconductor layer 4 is formed on the gate insulating film 37, and the gate insulating film 5 is formed covering the formed oxide semiconductor layer 4. Furthermore, the gate electrode 6 is formed on the gate insulating film 5, and the passivation film 7 is formed conforming to the formed gate electrode 6.

The transistor 41 has a double gate structure in which electrodes are provided in an upper portion (the gate electrode 6) and a lower portion (the gate electrode 36) with the oxide semiconductor layer 4 interposed therebetween. The same voltage is applied to the gate electrode 6 and the gate electrode 36. Thus, the driving of the transistor 41 is controlled by the voltage applied to the gate electrode 6 and the gate electrode 36. Different voltages may be applied to the gate electrode 6 and the gate electrode 36. In this case, the driving of the transistor 41 may be controlled by a voltage applied to the gate electrode 6, and a constant potential may be applied to the gate electrode 36 to assist the driving of the transistor 41.

### Method for Manufacturing Transistor 41

The method for manufacturing the transistor 41 is substantially the same as the method for manufacturing the transistor 1 according to the first embodiment except that a process for forming the gate electrode 36 and a process for forming a gate insulating film 37 are added.

### Advantageous Effects

Therefore, also in the transistor 41 having the double gate structure, the low resistance of the first region 4b and the second region 4c of the oxide semiconductor layer 4 is maintained, so that it is possible to suppress a decrease in the on-characteristics of the TFT and to suppress a significant decrease in the on-current.

In the first to fourth embodiments described above, boron ions (B+) are used as impurities to be implanted into the oxide semiconductor layer 4. However, the impurities are not limited to boron ions and may be any ions that can cause oxygen deficiency in the oxide semiconductor layer 4. Even when other ions are used, the position of the peak of the concentration of the ions to be implanted may not be in the oxide semiconductor layer 4 and may be at the interface between the gate insulating film 5 and the oxide semiconductor layer 4 or on the gate insulating film 5 side.

In the first to fourth embodiments described above, only boron ions (B+) are implanted as impurities into the oxide semiconductor layer 4. However, for example, hydrogen ions may be implanted in addition to the boron ions (B+). The method for implanting hydrogen ions in addition to boron ions (B+) can be realized by implanting divalent boron (BH+, B₂H₅+, or the like). Instead of divalent boron, for example, divalent phosphorus (PH+) may be used. The addition of hydrogen ions to the impurities brings about an effect of increasing the stability of the impurity implantation.

In the first to fourth embodiments described above, an In—Ga—Zn—O based semiconductor is used as the oxide semiconductor layer 4. However, no such limitation is intended, and instead of the In—Ga—Zn—O based semiconductor, another oxide semiconductor may be used. An In—Sn—Zn—O based semiconductor may be included as the oxide semiconductor layer 4, for example. The In—Sn—Zn—O based semiconductor is a ternary oxide of In, Sn, and Zn, and examples thereof include In₂O₃—SnO₂—ZnO (InSnZnO).

The oxide semiconductor layer 4 is not limited to this, but may include an In—Al—Zn—O based semiconductor, an In—Al—Sn—Zn—O based semiconductor, a Zn—O based semiconductor, an In—Zn—O based semiconductor, a Zn—Ti—O based semiconductor, a Cd—Ge—O based semiconductor, a Cd—Pb—O based semiconductor, cadmium oxide (CdO), a Mg—Zn—O based semiconductor, an In—Ga—Sn—O based semiconductor, a Zr—In—Zn—O based semiconductor, a Hf—In—Zn—O based semiconductor, an Al—Ga—Zn—O based semiconductor, a Ga—Zn—O based semiconductor, an In—Ga—Zn—Sn—O based semiconductor, InGaO₃(ZnO)₅, magnesium zinc oxide (Mg_{X}Zn₁₋ₓO), cadmium zinc oxide (Cd_{X}Zn₁₋ₓO), or the like. As the Zn—O based semiconductor, a semiconductor in an amorphous state of ZnO to which an impurity element of one kind or a plurality of kinds among a first group element, a 13-th group element, a 14-th group element, a 15-th group element, or a 17-th group element is added, a polycrystalline state, or a microcrystalline state in which the amorphous state and the polycrystalline state are mixed, or a semiconductor to which no impurity element is added can be used.

### EXAMPLES

In the examples, a display device using the transistors 1, 21, 31 described in the first to third embodiments will be described.

### Overview of Display Device

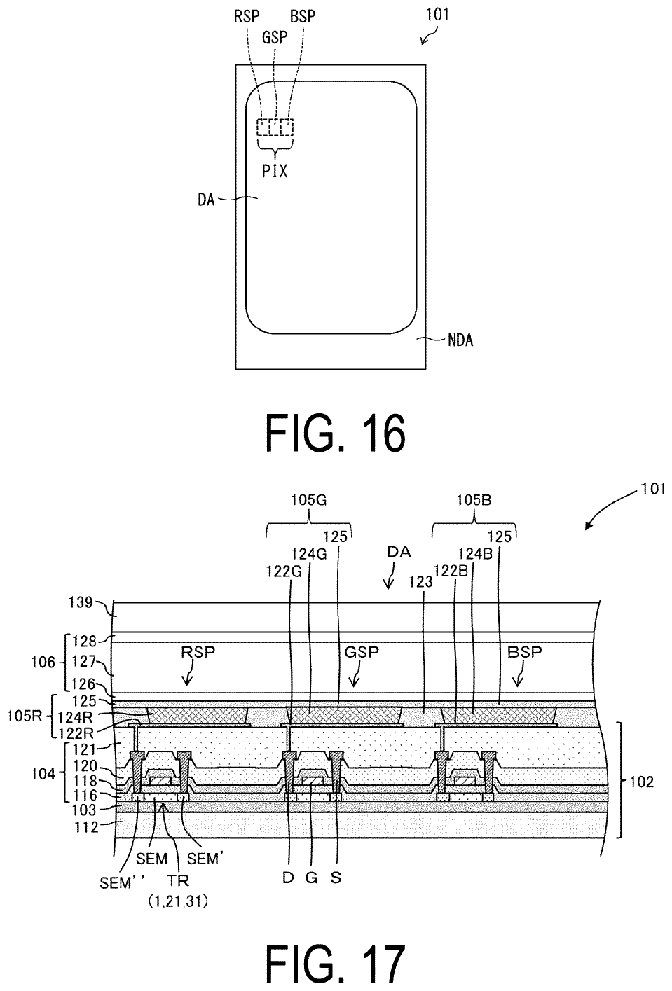

FIG. 16 is a plan view showing a schematic configuration of a display device 101 according to the present example. As illustrated in FIG. 16, the display device 101 includes a frame region NDA and a display region DA. A plurality of pixels PIX are provided in the display region DA of the display device 101, and each pixel PIX includes a red subpixel RSP, a green subpixel GSP, and a blue subpixel BSP. In the present example, a case will be described as an example in which one pixel PIX includes the red subpixel RSP, the green subpixel GSP, and the blue subpixel BSP, but the disclosure is not limited thereto. For example, one pixel PIX may further include a subpixel of another color in addition to the red subpixel RSP, the green subpixel GSP, and the blue subpixel BSP.

FIG. 17 is a cross-sectional view illustrating a schematic configuration of the display region DA of the display device 101 according to the present example. As illustrated in FIG. 17, in the display region DA of the display device 101, a barrier layer 103, a thin film transistor layer 104 including transistors TR, a red light-emitting element 105R, a green light-emitting element 105G, a blue light-emitting element 105B, and a bank 123 (transparent resin layer), a sealing layer 106, and a function film 139 are provided on a substrate 112 in this order from the substrate 112 side. As illustrated in FIG. 17, a substrate in which the barrier layer 103, the thin film transistor layer 104 including the transistors TR, and a plurality of first electrodes 122R, 122G, 122B are provided on the substrate 112 in this order from the substrate 112 side corresponds to a substrate (active matrix substrate) 102 including a first electrode. That is, the display device 101 includes the substrate 102 and the transistors TR (1, 21, 31), which are semiconductor devices, on the substrate 102.

The red subpixel RSP provided in the display region DA of the display device 101 includes the red light-emitting element 105R (first light-emitting element), the green subpixel GSP provided in the display region DA of the display device 101 includes the green light-emitting element 105G (second light-emitting element), and the blue subpixel BSP provided in the display region DA of the display device 101 includes the blue light-emitting element 105B (third light-emitting element). The red light-emitting element 105R included in the red subpixel RSP includes a first electrode 122R, a function layer 124R including a red light-emitting layer, and a second electrode 125, the green light-emitting element 105G included in the green subpixel GSP includes a first electrode 122G, a function layer 124G including a green light-emitting layer, and the second electrode 125, and the blue light-emitting element 105B included in the blue subpixel BSP includes a first electrode 122B, a function layer 124B including a blue light-emitting layer, and the second electrode 125. In the present embodiment described here, the first electrode 122R included in the red subpixel RSP, the first electrode 122G included in the green subpixel GSP, and the first electrode 122B included in the blue subpixel BSP are electrodes formed from the same material in the same process. However, no such limitation is intended.

The substrate 112 may be, for example, a resin substrate made of a resin material such as polyimide, or may be a glass substrate. In the present embodiment, the display device 101 is a flexible display device, and thus a case will be described as an example in which the resin substrate made of the resin material such as polyimide is used as the substrate 112. However, the disclosure is not limited thereto. In a case where the display device 101 is a non-flexible display device, the glass substrate may be used as the substrate 112.

The barrier layer 103 is a layer that inhibits foreign matter, such as water and oxygen, from entering the transistor TR, the red light-emitting element 105R, the green light-emitting element 105G, and the blue light-emitting element 105B, and can be formed of, for example, a silicon oxide film, a silicon nitride film, or a silicon oxynitride film, or a layered film thereof formed by chemical vapor deposition (CVD).

The transistor TR portion of the thin film transistor layer 104 including the transistor TR includes a semiconductor film SEM, doped semiconductor films SEM′ and SEM″, an inorganic insulating film 116, a gate electrode G, an inorganic insulating film 118, an inorganic insulating film 120, a source electrode S, a drain electrode D, and a flattening film 121. A portion other than the transistor TR portion of the thin film transistor layer 104 including the transistor TR includes the inorganic insulating film 116, the inorganic insulating film 118, the inorganic insulating film 120, and the flattening film 121.

The semiconductor films SEM, SEM′ and SEM″ may be formed of low-temperature polysilicon (LTPS) or an oxide semiconductor (for example, an In—Ga—Zn—O based semiconductor), for example. In the present example, a case will be described as an example in which the transistor TR (1, 21, 31) has a top gate structure. However, no such limitation is intended, and the transistor TR (1, 21, 31) may have a bottom gate structure or may be the transistor 41 with a double gate structure as described in the fourth embodiment.

The gate electrode G, the source electrode S, and the drain electrode D may be formed of a single-layer film or a layered film of a metal including, for example, at least one of aluminum, tungsten, molybdenum, tantalum, chromium, titanium, and copper.

The inorganic insulating film 116, the inorganic insulating film 118, and the inorganic insulating film 120 can be formed of, for example, a silicon oxide film, a silicon nitride film, or a silicon oxynitride film, or a layered film thereof, formed by CVD.

The flattening film 121 can be formed of coatable organic materials such as polyimide and acrylic.

The red light-emitting element 105R includes the first electrode 122R that is an upper layer overlying the flattening film 121, the function layer 124R including a red light-emitting layer, and the second electrode 125. The green light-emitting element 105G includes the first electrode 122G that is an upper layer overlying the flattening film 121, the function layer 124G including the green light-emitting layer, and the second electrode 125. The blue light-emitting element 105B includes the first electrode 122B that is an upper layer overlying the flattening film 121, the function layer 124B including the blue light-emitting layer, and the second electrode 125. Note that an insulating bank 123 (transparent resin layer) covering the edge of each of the first electrode 122R, the first electrode 122G, and the first electrode 122B can be formed, for example, by applying an organic material, such as a polyimide or acrylic, and then patterning the organic material by photolithography.

A control circuit including the transistors TR (1, 21, 31) each of which controls a respective one of the red light-emitting element 105R, the green light-emitting element 105G, and the blue light-emitting element 105B is provided in the thin film transistor layer 104 including the transistors TR corresponding to the red subpixel RSP, the green subpixel GSP, and the blue subpixel BSP. Note that the control circuit including the transistors TR provided corresponding to the red subpixel RSP, the green subpixel GSP, and the blue subpixel BSP and the light-emitting elements are collectively referred to as a subpixel circuit.

The red light-emitting element 105R, the green light-emitting element 105G, and the blue light-emitting element 105B will be described below in detail.

The sealing layer 106 is a transparent film and, for example, may be formed of an inorganic sealing film 126 for covering the second electrode 125, an organic film 127 that is an upper layer overlying the inorganic sealing film 126, and an inorganic sealing film 128 that is an upper layer overlying the organic film 127. The sealing layer 106 inhibits foreign matters such as water and oxygen from penetrating into the red light-emitting element 105R, the green light-emitting element 105G, and the blue light-emitting element 105B.

The inorganic sealing film 126 and the inorganic sealing film 128 are both inorganic films and may be formed of, for example, a silicon oxide film, a silicon nitride film, a silicon oxynitride film, or a layered film thereof, formed by CVD. The organic film 127 is a transparent organic film having a flattening effect, and may be formed of a coatable organic material such as acrylic, for example. The organic film 127 may be formed by an ink-jet method, for example. The case has been described as an example of the present example in which the sealing layer 106 is formed of two layers of an inorganic film and one layer of an organic film provided between the two layers of the inorganic film. However, the layering order of the two layers of the inorganic film and the one layer of the organic film is not limited thereto. Further, the sealing layer 106 may be formed of only an inorganic film, may be formed of only an organic film, may be formed of one layer of an inorganic film and two layers of an organic film, or may be formed of two or more layers of an inorganic film and two or more layers of an organic film.

The function film 139 is a film with at least one of an optical compensation function, a touch sensor function, and a protection function, for example.

### Light-Emitting Element

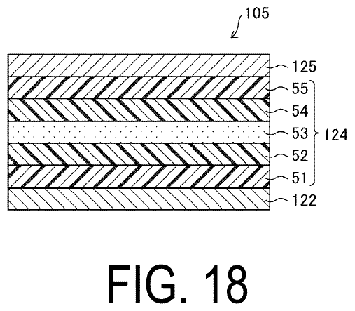

The red light-emitting element 105R, the green light-emitting element 105G, and the blue light-emitting element 105B included in the display device 101 will be described below with reference to FIGS. 17 and 18. Hereinafter, for the sake of convenience, the red light-emitting element 105R, the green light-emitting element 105G, and the blue light-emitting element 105B will be considered to have the same structure and described using light-emitting element 105.

FIG. 18 is a view schematically illustrating an example of a layered structure of the light-emitting element 105. In the present example, a quantum dot light-emitting diode (QLED) is used as an example of the light-emitting element 105.

In the present example, the light-emitting element 105 has a normal-order layered structure. However, no such limitation is intended, and the light-emitting element 105 may have a reverse-order layered structure. As illustrated in FIG. 18, the light-emitting element 105 having the normal-order layered structure includes the first electrode 122 serving as an anode, the second electrode 125 serving as a cathode provided as an upper layer overlying the first electrode 122, and the function layer 124 between the first electrode 122 serving as an anode and the second electrode 125 serving as a cathode. The function layer 124 is configured, for example, by layering, in order from the first electrode 122 side, a hole injection layer (HIL) 51, a hole transport layer (HTL) 52, a light-emitting layer (EML) 53, an electron transport layer (ETL) 54, and an electron injection layer (EIL) 55. Of the hole injection layer 51, the hole transport layer 52, the electron transport layer 54, and the electron injection layer 55 in the function layer 124, one or more layers except for the light-emitting layer 53 may be omitted as appropriate.

In a case where the light-emitting element has a reverse-order layered structure, though not illustrated, the light-emitting element includes a first electrode serving as a cathode and a second electrode serving as an anode provided as an upper layer overlying the first electrode, and the function layer provided between the first electrode serving as a cathode and the second electrode serving as an anode is configured of an electron injection layer, an electron transport layer, a red light-emitting layer, a hole transport layer, and a hole injection layer layered in this order from the first electrode side. Also, as with a light-emitting element having a normal-order layered structure, of the electron injection layer, the electron transport layer, the hole transport layer, and the hole injection layer in the function layer, one or more layers except that light-emitting layer may be omitted as appropriate.

In the present example, the first electrode 122 is also referred to as an anode electrode. The first electrode 122 has conductivity and has optical characteristics of, for example, reflecting a part of visible light and transmitting the rest. The first electrode 122 includes both electrode material that reflects visible light and electrode material that transmits visible light.

Examples of electrode material that reflects visible light include metal materials such as Al, Mg, Li and Ag, alloys of these metal materials, a layered body of the above metal materials and transparent metal oxides (for example, indium tin oxide (ITO), indium zinc oxide, and indium gallium zinc oxide), and a layered body of the alloys and the transparent metal oxides (for example, ITO/Ag/ITO).

Examples of electrode material that transmits visible light include a transparent metal oxide, a thin film made of a metal material such as Al and Ag, and a nanowire made of the metal material.

The first electrode 122 can be prepared by a typical electrode forming method. Examples of the method for preparing the first electrode 122 include a physical vapor deposition (PVD) method and a chemical vapor deposition (CVD) method. Examples of the physical vapor deposition method include a vacuum vapor deposition method, a sputtering method, an electron beam (EB) vapor deposition method, and an ion plating method. Examples of a method for patterning the first electrode 122 include a photolithography method and an ink-jet method.

The hole injection layer 51 is configured of hole injection material capable of stabilizing the injection of holes into the light-emitting layer 53. Examples of the hole injection material include poly(3,4-ethylenedioxythiophene):polystyrene sulfonate (PEDOT:PSS), NiO, and CuSCN.

The hole transport layer 52 is configured of hole transport material capable of stabilizing the transportation of holes into the light-emitting layer 53. Examples of the hole transport material include poly[(9,9-dioctylfluorenyl-2,7-diyl)-co-(4,4′-(N-4-sec-butylphenyl)) diphenylamine)] (TFB) and poly[N,N′-bis(4-butylphenyl)-N,N′-bis(phenyl)-benzidine] (poly-TPD).

The light-emitting layer (EML) 53 is configured of quantum dots (QDs). Note that QD means a dot having a maximum width of 100 nm or less. The shape of the QD may be a spherical three-dimensional shape (with a circular cross-sectional shape) or may be, for example, a polygonal cross-sectional shape, a rod-shaped three-dimensional shape, a branch-shaped three-dimensional shape, or a three-dimensional shape having unevenness on the surface thereof, or a combination thereof.

The QDs may have, for example, a core structure, a core/shell structure, a core/shell/shell structure, or a core/shell with continuously varying ratio structure. The QD may include a ligand, and when the QD has a core structure, the ligand is provided on the surface of the core structure, and when the QD has a shell structure, the ligand is provided on the surface of the shell structure.

The material constituting the core structure of the QD includes Si and C in the case of a mono-component system. In the case of a binary system, examples of the material include: CdSe, CdS, CdTe, InP, GaP, InN, ZnSe, ZnS, and ZnTe. In the case of a ternary system, examples of the material include: CdSeTe, GaInP, and ZnSeTe. In the case of a quaternary system, an example of the material includes AIGS.

In the case of a binary system, examples of the material configuring the shell structure of the QD include: CdS, CdTe, CdSe, ZnS, ZnSe, and ZnTe. In the case of a ternary system, examples of the material include: CdSSe, CdTeSe, CdSTe, ZnSSe, ZnSTe, ZnTeSe, and AIP.

The electron transport layer 54 is configured of electron transport material capable of stabilizing the transportation of electrons into the light-emitting layer 53. In the present example, MgZnO-PVP nanoparticles (MgZnO-PVP-NPs) is used. MgZnO-PVP-NPs has a shell structure of PVP and a core structure of MgZnO as an electron transport material and has a particle size of nano order. MgZnOPVP-NPs corresponds to the composite material nanoparticles described above. Examples of the electron transport material include nanoparticles including one or more elements selected from the group consisting of Zn, Mg, Ti, Si, Sn, W, Ta, Ba, Zr, Al, Y, and Hf in addition to MgZnO.

The electron injection layer 55 is configured of electron injection material capable of stabilizing the injection of electrons into the light-emitting layer 53. Examples of the electron injection material include quinoline, perylene, phenanthroline, bisstyryl, pyrazine, triazole, oxazole, oxadiazole, fluorenone, and derivatives and metal complexes thereof, and lithium fluoride (LiF).

In the present example, the second electrode 125 is also referred to as a cathode electrode. The second electrode 125 has, for example, conductivity and transparency to visible light. Examples of the electrode material constituting the second electrode 125 include ITO and Ag nanowire (NW). The second electrode 125 can be formed of the electrode material described above for the first electrode 122, and can be prepared by the method described above for the first electrode 122 in accordance with the electrode material. The second electrode 125 is formed on the entire surface of the light-emitting element 105 on the side opposite the first electrode 122 with the function layer 124 interposed therebetween and covers the electron injection layer 55, the bank 123, and the thin film transistor layer 104.

In the present example, as illustrated in FIG. 17, each of the function layer 124R including the red light-emitting element 105R, the function layer 124G including the green light-emitting element 105G, and the function layer 124B including the blue light-emitting element 105B includes the hole injection layer 51 formed using the same material in the same process, the hole transport layer 52 formed using the same material in the same process, the electron transport layer 54 formed using the same material in the same process, and the electron injection layer 55 formed using the same material in the same process. However, no such limitation is intended. For example, the hole injection layers 51 included respectively in the function layers 124R, 124G, and 124B may be formed of materials different from each other. For example, the hole injection layers 51 each included in a respective one of two function layers of the function layers 124R, 124G, and 124B may be formed of the same material in the same process, and only the hole injection layer included in the remaining one function layer may be formed of a different material in another process. In addition, for example, the hole transport layers 52 included respectively in the function layers 124R, 124G, and 124B may be formed of materials different from each other. For example, the hole transport layers 52 included respectively in two function layers of the function layers 124R, 124G, and 124B may be formed of the same material in the same process, and only the hole transport layer 52 included in the remaining one function layer may be formed of a different material in another process. For example, the electron transport layers 54 included respectively in the function layers 124R, 124G, and 124B may be formed of materials different from each other. For example, the electron transport layers 54 included respectively in two function layers of the function layers 124R, 124G, and 124B may be formed of the same material in the same process, and only the electron transport layer 54 included in the remaining one function layer may be formed of a different material in another process. In addition, for example, the electron injection layers 55 included respectively in the function layers 124R, 124G, and 124B may be formed of materials different from each other. For example, the electron injection layers 55 included respectively in two function layers of the function layers 124R, 124G, and 124B may be formed of the same material in the same process, and only the electron injection layer 55 included in the remaining one function layer may be formed of a different material in another process.

The light-emitting element 105 has been described as a QLED. Thus, although the red light-emitting element 105R, the green light-emitting element 105G, and the blue light-emitting element 105B illustrated in FIG. 17 are all QLEDs, no such limitation is intended. One or more of the red light-emitting elements 105R, the green light-emitting elements 105G, and the blue light-emitting elements 105B may be QLEDs, and the remaining of the red light-emitting element 105R, the green light-emitting element 105G, and the blue light-emitting element 105B may be OLEDs (Organic Light-Emitting Diodes). Also, the red light-emitting element 105R, the green light-emitting element 105G, and the blue light-emitting element 105B may be OLEDs. Note that when the red light-emitting element 105R, the green light-emitting element 105G, and the blue light-emitting element 105B are QLEDs, the light-emitting layer included in each of the light-emitting elements with the respective colors is a light-emitting layer including a quantum dot formed by, for example, a coating method or an ink-jet method. When each of the red light-emitting element 105R, the green light-emitting element 105G, and the blue light-emitting element 105B is an OLED, the light-emitting layer included in each of the light-emitting elements with the respective colors is an organic light-emitting layer formed by, for example, vapor deposition.

The red light-emitting element 105R, the green light-emitting element 105G, and the blue light-emitting element 105B illustrated in FIG. 17 may be a top-emitting type or a bottom-emitting type. The red light-emitting element 105R, the green light-emitting element 105G, and the blue light-emitting element 105B have a normal-order layered structure with the second electrode 125 serving as a cathode disposed as the upper layer overlying the first electrodes 122R, 122G, 122B serving as anodes. Thus, to achieve a top-emitting type, the first electrodes 122R, 122G, 122B serving as anodes are made of an electrode material that reflects visible light, and the second electrode 125 serving as the cathode is made of an electrode material that transmits visible light. To achieve a bottom-emitting type, the first electrodes 122R, 122G, 122B serving as anodes are made of an electrode material that transmits visible light, and the second electrode 125 serving as the cathode is made of an electrode material that reflects visible light. On the other hand, in a case where the red light-emitting element, the green light-emitting element, and the blue light-emitting element have a reverse-order layered structure with the second electrode serving as an anode disposed as the upper layer overlying the first electrodes serving as cathodes, to achieve a top-emitting type, the first electrodes serving as cathodes are made of an electrode material that reflects visible light, and the second electrode serving as the anode is made of an electrode material that transmits visible light. To achieve a bottom-emitting type, the first electrodes serving as cathodes are made of an electrode material that transmits visible light, and the second electrode serving as the anode is made of an electrode material that reflects visible light.

The electrode material that reflects visible light is not particularly limited as long as the material can reflect visible light and has electrical conductivity. Examples include metal materials such as Al, Mg, Li, and Ag, alloys of the metal materials, a layered body of the metal materials and transparent metal oxides (for example, indium tin oxide, indium zinc oxide, indium gallium zinc oxide, and the like), or a layered body of the alloys and the transparent metal oxides.

On the other hand, the electrode material that transmits visible light is not particularly limited as long as the material can transmit visible light and has electrical conductivity. Examples include a thin film formed of a transparent metal oxide (for example, indium tin oxide, indium zinc oxide, indium gallium zinc oxide, and the like) or a metal material such as Al and Ag, or a nano wire formed of a metal material such as Al and Ag.

A typical electrode forming method may be used as a film formation method of the first electrodes 122R, 122G, and 122B and the second electrode 125, and examples thereof include physical vapor deposition (PVD) such as vacuum vapor deposition, a sputtering method, electron beam (EB) vapor deposition, and an ion plating method, or chemical vapor deposition (CVD). Further, the method of patterning the first electrodes 122R, 122G, and 122B and the second electrode 125 is not particularly limited as long as the method is capable of precisely forming a desired pattern, and specific examples thereof include a photolithography method and an ink-jet method.

### Supplement

A semiconductor device according to a first aspect of the disclosure includes an oxide semiconductor layer (4), a gate insulating film (5), and a gate electrode (6) layered in this order on a substrate (2), wherein the oxide semiconductor layer (4) includes a channel region (4a) overlapping the gate electrode (6) interposed by the gate insulating film (5), a first region (4b) electrically connected to a source electrode (8), and a second region (4c) electrically connected to a drain electrode (9), an impurity (boron ion (B+)) corresponding to an oxygen-defect-inducing factor is implanted in at least the gate insulating film (5), and the first region (4b) and the second region (4c), and an amount of impurity (boron ion (B+)) implanted in the gate insulating film (5) is greater than an amount of impurity (boron ion (B+)) implanted in the first region (4b) and the second region (4c).

According to the above configuration, the amount of the impurity implanted in the gate insulating film is greater than the amount of the impurity implanted into the first region and the second region of the oxide semiconductor layer, that is, the boron ions (B+) are implanted so that the peak of the concentration of the boron ions (B+) is located at the interface between the gate insulating film and the oxide semiconductor layer. Thus, oxygen defects are efficiently formed at the interface between the gate insulating film and the oxide semiconductor layer, and the resistance of the oxide semiconductor layer is reduced. Thus, the low-resistance regions of the oxide semiconductor layer are less likely to be increased in resistance by the supply of oxygen even if oxygen is supplied to the oxide semiconductor layer in the case of a heating process being performed after the implantation of the boron ions (B+) and are kept in a low-resistance state. Thus, even in the case where the heating process is performed after the impurity is implanted into the oxide semiconductor layer, the low resistance state of the low-resistance regions of the oxide semiconductor layer is maintained, so that a semiconductor device in which the low-resistance regions of the oxide semiconductor layer are stably formed can be realized.

The semiconductor device according to a second aspect of the disclosure is the semiconductor device according to the first aspect, wherein the oxide semiconductor layer (4) further includes a third region (4d) formed between the channel region (4a) and the first region (4b) and between the channel region (4a) and the second region (4c), an impurity (boron ions (B+)) corresponding to an oxygen-defect-inducing factor is implanted in the third region (4d), and an amount of impurity (boron ions (B+)) implanted in the third region (4d) is less than an amount of impurity (boron ions (B+)) implanted in the first region (4b) and the second region (4c).

According to the above configuration, since the third region provided on both sides of the channel region of the oxide semiconductor layer has a smaller amount of implanted impurity than the first region and the second region on the outer sides, the third region becomes a high-resistance region having a higher resistance value than the first region and the second region. Thus, the high-resistance region of the oxide semiconductor layer with the channel region at the center can be widened, so that resistance to application of a high voltage between the source electrode and the drain electrode can be increased. Thus, the reliability of the semiconductor device can be improved.

The semiconductor device according to a third aspect of the disclosure is the semiconductor device according to the first aspect, wherein a region of the oxide semiconductor layer (4) that the gate electrode (6) projects over includes the channel region (4a) and a fourth region (4e) formed on either side of the channel region (4a), and a resistance value of the fourth region (4e) is higher than a resistance value of the first region (4b) and the second region (4c) and less than a resistance value of the channel region (4a). According to the above configuration, a TFT with a channel length shorter than the width of the gate electrode can be formed.

A method for manufacturing a semiconductor device according to a fourth aspect of the disclosure, with the semiconductor device including an oxide semiconductor layer (4), a gate insulating film (5), and a gate electrode (6) layered in this order on a substrate (2), includes forming the oxide semiconductor layer (4) on the substrate (2); forming the gate insulating film (5) on the oxide semiconductor layer (4); forming the gate electrode (6) on the gate insulating film (5); and implanting an impurity (boron ions (B+)) corresponding to an oxygen-defect-inducing factor from above the gate insulating film (5), wherein in the implanting, the impurity (boron ions (B+)) is implanted so that a peak of concentration of the impurity (boron ions (B+)) is located in the gate insulating film (5).

According to the above configuration, in the impurity implantation process, the impurity is implanted so that the peak of the concentration of the impurity is located in the gate insulating film. Thus, oxygen defects are efficiently formed at the interface between the gate insulating film and the oxide semiconductor layer, and the resistance of the oxide semiconductor layer is reduced. Thus, the low-resistance regions of the oxide semiconductor layer are less likely to be increased in resistance by the supply of oxygen even if oxygen is supplied to the oxide semiconductor layer in the case of a heating process being performed after the implantation of the boron ions (B+) and are kept in a low-resistance state. Thus, even in the case where the heating process is performed after the impurity is implanted into the oxide semiconductor layer, the low resistance state of the low-resistance regions of the oxide semiconductor layer is maintained, so that a semiconductor device in which the low-resistance regions of the oxide semiconductor layer are stably formed can be realized.

The method for manufacturing a semiconductor device according to a fifth aspect of the disclosure is the method according to the fourth aspect, wherein in the implanting, the impurity (boron ions (B+)) is implanted so that a peak of concentration of the impurity (boron ions (B+)) is located at an interface between the gate insulating film (5) and the oxide semiconductor layer (4).

The method for manufacturing a semiconductor device according to a sixth aspect of the disclosure is the method according to the fourth or fifth aspect, wherein in the implanting, an impurity (boron ions (B+)) corresponding to an oxygen-defect-inducing factor is implanted from above the gate insulating film (5) after the gate electrode (6) is formed on the gate insulating film (5). In this case, since the gate electrode serves as a mask when the impurity is implanted, the impurity is not implanted into the region of the oxide semiconductor layer that the gate electrode projects over. That is, the region of the oxide semiconductor layer that the gate electrode projects over can serve as a channel region.

In the method for manufacturing a semiconductor device according to a seventh aspect of the disclosure, preferably in the implanting, an impurity (boron ions (B+)) corresponding to an oxygen-defect-inducing factor is implanted from above the gate insulating film (5) after the gate electrode (6) is formed on the gate insulating film (5) and a photoresist is formed covering the gate electrode (6). In this case, since the photoresist covering the gate electrode serves as a mask when the impurity is implanted, the impurity is not implanted into a region wider than the region of the oxide semiconductor layer that the gate electrode projects over. That is, the region of the oxide semiconductor layer that the gate electrode projects over can be artificially widened as a high-resistance region such as the channel region. Thus, resistance to application of a high voltage between the source electrode and the drain electrode can be increased. Thus, the reliability of the semiconductor device can be improved.

The method for manufacturing a semiconductor device according an eighth aspect of the disclosure is the method according to the fourth or fifth aspect, the method further including forming a photoresist (11) before the forming of the gate electrode, the photoresist (11) being formed on the gate insulating film (5) in a region including a planned region for forming the gate electrode (6), the region being wider than the planned region, preliminarily implanting an impurity (boron ions (B+)) corresponding to an oxygen-defect-inducing factor from above the gate insulating film (5) after the photoresist (11) is formed on the gate insulating film (5), and removing the photoresist (11) after an impurity (boron ions (B+)) is implanted in the preliminarily implanting, wherein in the implanting, an impurity (boron ions (B+)) corresponding to an oxygen-defect-inducing factor is implanted from above the gate insulating film (5) after the photoresist (11) is removed by the removing and the gate electrode (6) is formed on the gate insulating film (5).

According to the above structure, the oxide semiconductor layer includes a region into which the impurity is implanted once and a region into which the impurity is implanted twice, and the region into which the impurity is implanted twice has a larger amount of the impurity than the region into which the impurity is implanted once, and thus has a lower resistance value. In addition, since the photoresist formed in the region narrower than the region where the gate electrode is formed is used as a mask before the gate electrode is formed in the first impurity implantation, the channel region having a width shorter than the width of the gate electrode can be formed in the region of the oxide semiconductor layer that the gate electrode projects over.

The method for manufacturing a semiconductor device according to a ninth aspect of the disclosure is the method according to the eighth aspect, wherein in the preliminarily implanting, preferably the impurity (boron ions (B+)) is implanted so that a peak of concentration of the impurity (boron ions (B+)) is located beyond an interface between the gate insulating film (5) and the oxide semiconductor layer (4) and on a side of the oxide semiconductor layer (4).

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

1-4. (canceled)

5. A method for manufacturing a semiconductor device including an oxide semiconductor layer, a gate insulating film, and a gate electrode layered in this order on a substrate, comprising:
forming the oxide semiconductor layer on the substrate;
forming the gate insulating film on the oxide semiconductor layer;
forming the gate electrode on the gate insulating film; and
implanting an impurity corresponding to an oxygen-defect-inducing factor from above the gate insulating film, wherein
in the implanting, the impurity is implanted so that a peak of concentration of the impurity is located in the gate insulating film, and
the impurity corresponding to the oxygen-defect-inducing factor is implanted from above the gate insulating film after the gate electrode is formed on the gate insulating film and a photoresist is formed covering the gate electrode.

6. The method for manufacturing a semiconductor device according to claim 5,
wherein in the implanting, the impurity is implanted so that a peak of concentration of the impurity is located at an interface between the gate insulating film and the oxide semiconductor layer.

7. (canceled)

8. (canceled)

9. A method for manufacturing a semiconductor device including an oxide semiconductor layer, a gate insulating film, and a gate electrode layered in this order on a substrate, comprising:
forming the oxide semiconductor layer on the substrate;
forming the gate insulating film on the oxide semiconductor layer;
forming the gate electrode on the gate insulating film; and
implanting an impurity corresponding to an oxygen-defect-inducing factor from above the gate insulating film, wherein
in the implanting, the impurity is implanted so that a peak of concentration of the impurity is located in the gate insulating film,
the method for manufacturing a semiconductor device further comprises:
forming a photoresist before the forming of the gate electrode, the photoresist being formed on the gate insulating film in a region including a planned region for forming the gate electrode, the region being wider than the planned region;
preliminarily implanting the impurity corresponding to the oxygen-defect-inducing factor from above the gate insulating film after the photoresist is formed on the gate insulating film; and
removing the photoresist after the impurity is implanted in the preliminarily implanting,
wherein in the implanting, the impurity corresponding to the oxygen-defect-inducing factor is implanted from above the gate insulating film after the photoresist is removed by the removing and the gate electrode is formed on the gate insulating film.

10. The method for manufacturing a semiconductor device according to claim 9,
wherein in the preliminarily implanting, the impurity is implanted so that a peak of concentration of the impurity is located beyond an interface between the gate insulating film and the oxide semiconductor layer and on a side of the oxide semiconductor layer.

11. The method for manufacturing a semiconductor device according to claim 9,
wherein in the implanting, the impurity is implanted so that a peak of concentration of the impurity is located at an interface between the gate insulating film and the oxide semiconductor layer.
